(19) United States
(12) Patent Application Publication
(10) Pub. No.: US 2003/0107424 A1
(43) Pub. Date: Jun. 12, 2003

(54) ESD protection circuit

(76) Inventor: Chien-Chang Huang, Hsin-Chu (TW)

Correspondence Address: Merchant & Gould P.C., P.O. Box 2903, Minneapolis, MN, 55402-0903, US

(21) Appl. No.: 10/068,204

(22) Filed: Feb. 5, 2002

(30) Foreign Application Priority Data
Dec. 11, 2001 (TW) 90130701

(51) Int. Cl. H03L 5/00

(52) U.S. Cl. 327/310

(57) ABSTRACT

An ESD protection circuit protecting an internal circuit from ESD damage. The internal circuit is connected to a voltage interface and powered by a first and second power supply. A first signal with a first amplitude received from a pad is transformed to a second signal with a second amplitude by the voltage interface. The second signal is input to the internal circuit. A first and second diode are serially but inversely connected between the pad and the first power supply. The ESD protection circuit comprises a first transistor having a source connected to a node between the first and second diode, a first inverter having an output connected to a gate of the first transistor, a first resistor connected between the source of the first transistor and an input of the inverter, a first capacitor connected between the input of the inverter and the second power supply, and a clamping circuit connected between the input of the inverter and the second power supply, and clamping a voltage level on the input of the inverter.

### BACKGROUND OF THE INVENTION

1. Field of the Invention

The present invention relates to an ESD protection circuit, particularly to an ESD protection circuit protecting an internal circuit connected to a voltage interface from ESD damage.

2. Description of the Prior Art

FIG. 1 is a diagram showing a conventional ESD protection circuit protecting an internal circuit 11 connected to a voltage interface 12. The ESD protection circuit comprises an output buffer 13, a pad 14 for input, a pad 15 for output, four protecting circuit 16a, 16b, 17a, 17b, a floating ESD bus 18, a diode 19 and a resistor R. All the active elements are powered by two power supplies providing a positive and negative voltage VDD and VSS.

The voltage interface 12 transforms the amplitude of the input signal on the pad 14 from 5V to 3V to be compatible with the internal circuit 11 powered by the power supply providing an operating voltage of 3V. The internal circuit 11 receives the transformed input signal and generates an output signal to the output buffer 13 which drives the output signal on the pad 15.

The output buffer 13 comprises two transistors 131 and 132 having conductivity opposite to each other. The protection circuits 16a and 16b comprise diodes 161a, 162a and 161b, 162b serially connected in the same direction respectively. The protection circuits 17a and 17b comprise transistors 171a, 171b, inverters 172a, 172b, resistors 173a, 173b, and capacitors 174a, 174b respectively.

In the protection circuit 17a, the transistor 171a has a source connected to the floating ESD bus 18 between the diodes 161a and 19, and a drain connected to VSS. The inverter 172a has an output connected to a gate of the transistor 171a. The resistor 173a is connected between the source of the transistor 171a and an input of the inverter 172a. The capacitor 174a is connected between the input of the inverter 172a and VSS.

In the protection circuit 17b, the transistor 171b has a source connected to VDD and a drain connected to VSS. The inverter 172b has an output connected to a gate of the transistor 171b. The resistor 173b is connected between an input of the inverter 172b and VDD. The capacitor 174b is connected between the input of the inverter 172b and VSS.

The protection circuits 16a and 17a establish an ESD path from pad 14 to VSS, the protection circuit 16b establishes an ESD path from pad 15 to VDD or VSS, and the protection circuit 17b establishes an ESD path from VDD to VSS. Thus, the internal circuit 11 is protected from ESD damage since the electrical charges generated on the pad 14, 15 or one of the power supplies are discharged through one of the paths established by the protection circuits 16a, 16b, 17a and 17b.

During normal operation of the internal circuit 11, the diode 19 inversely connected with the diode 161a cuts off a conductive path from VDD to the pad 14 so that the ESD bus 18 is floating.

However, in the conventional ESD protection circuit, there accumulates a large number of charges on the floating ESD bus 18 after a long period of operation of the internal circuit 11 due to a charge coupling effect induced by the input signal received by the voltage interface 12. The charges accumulated on the ESD bus 18 generate a high voltage level which deteriorates the reliability of the circuit.

### SUMMARY OF THE INVENTION

Therefore, the object of the present invention is to provide an ESD protection circuit protecting an internal circuit connected to a 5V-to-3V voltage interface. The ESD protection circuit clamps the voltage level on the ESD bus.

The present invention provides an ESD protection circuit protecting an internal circuit from ESD damage. The internal circuit is connected to a voltage interface and powered by a first and second power supply. A first signal with a first amplitude received from a pad is transformed to a second signal with a second amplitude by the voltage interface. The second signal is input to the internal circuit. A first and second diode are serially but inversely connected between the pad and the first power supply. The ESD protection circuit comprises a first transistor having a source connected to a node between the first and second diode, a first inverter having an output connected to a gate of the first transistor, a first resistor connected between the source of the first transistor and an input of the inverter, a first capacitor connected between the input of the inverter and the second power supply, and a clamping circuit connected between the input of the inverter and the second power supply, and clamping a voltage level on the input of the inverter.

Thus, in the invention, a clamping circuit is used to clamp the voltage on the ESD bus, which prevents the high voltage generated on the ESD bus and eliminates the circuit reliability issue.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1 is a diagram showing a conventional ESD protection circuit protecting an internal circuit connected to a voltage interface.

FIG. 2 is a diagram showing an ESD protection circuit protecting an internal circuit connected to a voltage interface according to one embodiment of the invention.

### DETAILED DESCRIPTION OF THE INVENTION

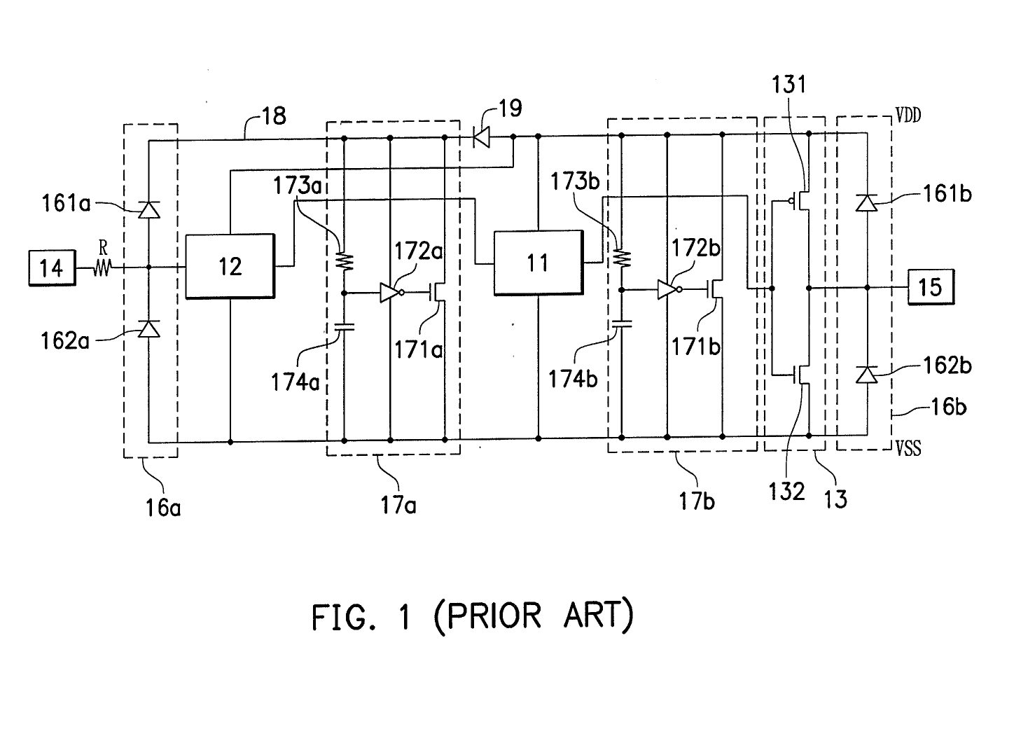

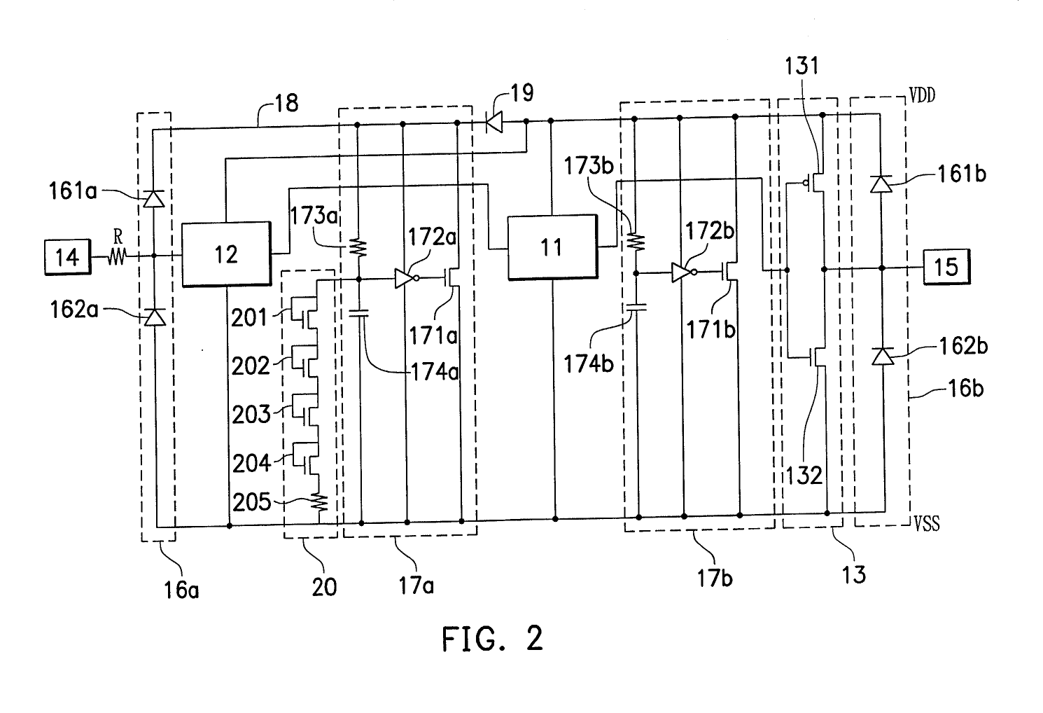

FIG. 2 is a diagram showing an ESD protection circuit protecting an internal circuit connected to a voltage interface according to one embodiment of the invention. The same elements in FIGS. 1 and 2 refer to the same symbols for clarity.

The ESD protection circuit comprises an output buffer 13, a pad 14 for input, a pad 15 for output, four protecting circuits 16a, 16b, 17a, 17b, a floating ESD bus 18, a diode 19, a resistor R and a clamping circuit 20. All the active elements are powered by two power supplies providing a positive and negative voltage VDD and VSS.

The voltage interface 12 transforms the amplitude of the input signal on the pad 14 from 5V to 3V to be compatible with the internal circuit 11 powered by the power supply providing an operating voltage of 3V. The internal circuit 11 receives the transformed input signal and generates an output signal to the output buffer 13 which drives the output signal on the pad 15.

The protection circuits 16a and 17a establish an ESD path from pad 14 to VSS, the protection circuit 16b establishes an ESD path from pad 15 to VDD or VSS, and the protection circuit 17b establishes an ESD path from VDD to VSS. Thus, the internal circuit 11 is protected from ESD damage since the electrical charges generated on the pad 14, 15 or one of the power supplies are discharged through one of the paths established by the protection circuits 16a, 16b, 17a and 17b.

By comparing FIG. 2 with FIG. 1, it is noted that there is an additional clamping circuit 20 in FIG. 2. The clamping circuit 20 comprises four transistors 201˜204 serially connected together and a resistor 205. Each of the transistors 201˜204 has a source and gate connected together, which forms a diode-connected transistor. The resistor 205 is connected between a drain of the transistor 204 and VSS.

During the normal operation of the internal circuit 11, there is a voltage drop of 0.7V on each of the diode-connected transistors 201˜204 of the clamping circuit 20. The total voltage drop on the diode-connected transistors 201˜204, the resistors 173a and 205 is about 4V and almost independent from the current flowing through the transistors 201˜204. Thus, the voltage level on the floating ESD bus is clamped to a limited value.

In conclusion, the present invention provides an ESD protection circuit protecting an internal circuit connected to a 5V-to-3V voltage interface. A clamping circuit is used to clamp the voltage on the ESD bus, which prevents the high voltage generated on the ESD bus and eliminates the circuit reliability issue

While the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An ESD protection circuit protecting an internal circuit from ESD damage, wherein the internal circuit is connected to a voltage interface and powered by a first and second power supply, a first signal with a first amplitude received from a pad is transformed to a second signal with a second amplitude by the voltage interface, the second signal is input to the internal circuit, and a first and a second diode are serially but inversely connected between the pad and the first power supply, the ESD protection circuit comprising:
a first transistor having a source connected to a node between the first and second diode;
a first inverter having an output connected to a gate of the first transistor;
a first resistor connected between the source of the first transistor and an input of the inverter;
a first capacitor connected between the input of the inverter and the second power supply; and
a clamping circuit connected between the input of the inverter and the second power supply, and clamping a voltage level on the input of the inverter.

2. The ESD protection circuit as claimed in claim 1 further comprising a third diode connecting the pad and the second power supply.

3. The ESD protection circuit as claimed in claim 1 further comprising:
a second transistor connected between the first and second power supplies having a source and drain connected to the first and second power supply respectively;
a second inverter having an output connected to a gate of the second transistor;
a second resistor connected between an input of the second inverter and the first power supply; and
a second capacitor connected between the input of the second inverter and the second power supply.

4. The ESD protection circuit as claimed in claim 1 wherein the clamping circuit comprises:
a third transistor having a source and gate connected together to the input of the inverter; and
a third resistor connected between a drain of the third transistor and the second power supply.

5. The ESD protection circuit as claimed in claim 1 wherein the clamping circuit comprises:
a plurality of third transistors connected serially, each of which having a source and gate connected together to the input of the inverter; and
a third resistor connected between a drain of one of the third transistors and the second power supply.

6. The ESD protection circuit as claimed in claim 5 wherein the number of the third transistor is 4 and the voltage level on the input of the first inverter is 3V.

7. The ESD protection circuit as claimed in claim 1 wherein the first and second power supplies provide a positive VDD and negative VSS voltage respectively.

8. The ESD protection circuit as claimed in claim 1 wherein the first and second amplitude are 5V and 3V respectively.
